(19) United States
(12) Patent Application Publication
(10) Pub. No.: US 2005/0051604 A1
(43) Pub. Date: Mar. 10, 2005

(54) Method and system for forming ball grid array ("BGA") packages

(75) Inventors: Jovanie D. Claver, Baguio City (PH); Ferdinand B. Arabe, Baguio City (PH)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/774,777

(22) Filed: Feb. 9, 2004

Related U.S. Application Data
(60) Provisional application No. 60/501,346, filed on Sep. 9, 2003.

(51) Int. Cl. B23K 31/00; B23K 31/02; B05D 1/32; H01L 21/44

(52) U.S. Cl. 228/180.22; 228/180.21; 427/282; 438/614

(57) ABSTRACT

According to one embodiment of the invention, a system for forming ball grid array packages includes a substrate and a stencil engaging a first surface of the substrate. The stencil includes a center region having a first set of generally circular holes formed therein and a first outer region disposed radially outwardly from the center region having a second set of generally circular holes formed therein. The diameter of each of the generally circular holes of the second set is greater than the diameter of each of the generally circular holes of the first set. The system further includes a solder paste disposed outwardly from the stencil and a squeegee operable to spread the solder paste over the stencil to fill the first and second set of generally circular holes, thereby creating a plurality of solder paste regions.

### RELATED APPLICATIONS

This application claims the benefit of Ser. No. 60/501,346 titled “Multi-Dimensioned Stencil Design for Ball Grid Arrays and Flip-Chip Packages,” filed provisionally on Sep. 9, 2003.

### TECHNICAL FIELD OF THE INVENTION

This invention relates generally to the field of integrated circuit packaging and, more specifically, to a method and system for forming ball grid array (“BGA”) packages.

### BACKGROUND OF THE INVENTION

Packaging of integrated circuits, such as ball grid arrays (“BGAs”), include encapsulating semiconductor chips and their associated components within a molding. A mold press compresses a mold compound between mold press die to allow the mold compound to cure. After curing, the mold press die are removed to obtain the completed, or partially completed, packages. However, current molding techniques, combined with the fact that integrated circuit packaging is resulting in thinner packages, often lead to warpage of the mold compound after removal of the mold press die due to residual stresses that build up during the cure process from the coefficient of thermal expansion mismatch. This warpage leads to many problems, such as a coplanarity problem that leads to poor quality, poor reliability, and difficult testing of the integrated circuit packages.

### SUMMARY OF THE INVENTION

According to one embodiment of the invention, a system for forming ball grid array packages includes a substrate and a stencil engaging a first surface of the substrate. The stencil includes a center region having a first set of generally circular holes formed therein and a first outer region disposed radially outwardly from the center region having a second set of generally circular holes formed therein. The diameter of each of the generally circular holes of the second set is greater than the diameter of each of the generally circular holes of the first set. The system further includes a solder paste disposed outwardly from the stencil and a squeegee operable to spread the solder paste over the stencil to fill the first and second set of generally circular holes, thereby creating a plurality of solder paste regions.

Some embodiments of the invention provide numerous technical advantages. Other embodiments may realize some, none, or all of these advantages. For example, BGA package warpage is considered in advance when designing the stencil. The stencils for depositing the solder paste are designed such that the hole diameters generally increase as their position moves from the center of the stencil to the edges. This compensates for any warpage that may take place during the molding process due to coefficient of thermal expansion mismatch, thereby leading to proper dimensions and tolerances for the completed BGA packages. This improves productivity and yield, and eliminates rework at the ball inspection process.

Other technical advantages are readily apparent to one skilled in the art from the following figures, descriptions, and claims.

### BRIEF DESCRIPTION OF THE DRAWINGS

For a more complete understanding of the invention, and for further features and advantages, reference is now made to the following description, taken in conjunction with the accompanying drawings, in which:

FIG. 1 is a plan view of a stencil used for forming ball grid array packages according to an embodiment of the invention; and

FIGS. 2A through 2C are a series of cross-sectional elevation views illustrating an example method of packaging ball grid arrays according to an embodiment of the invention.

### DETAILED DESCRIPTION OF EXAMPLE EMBODIMENTS OF THE INVENTION

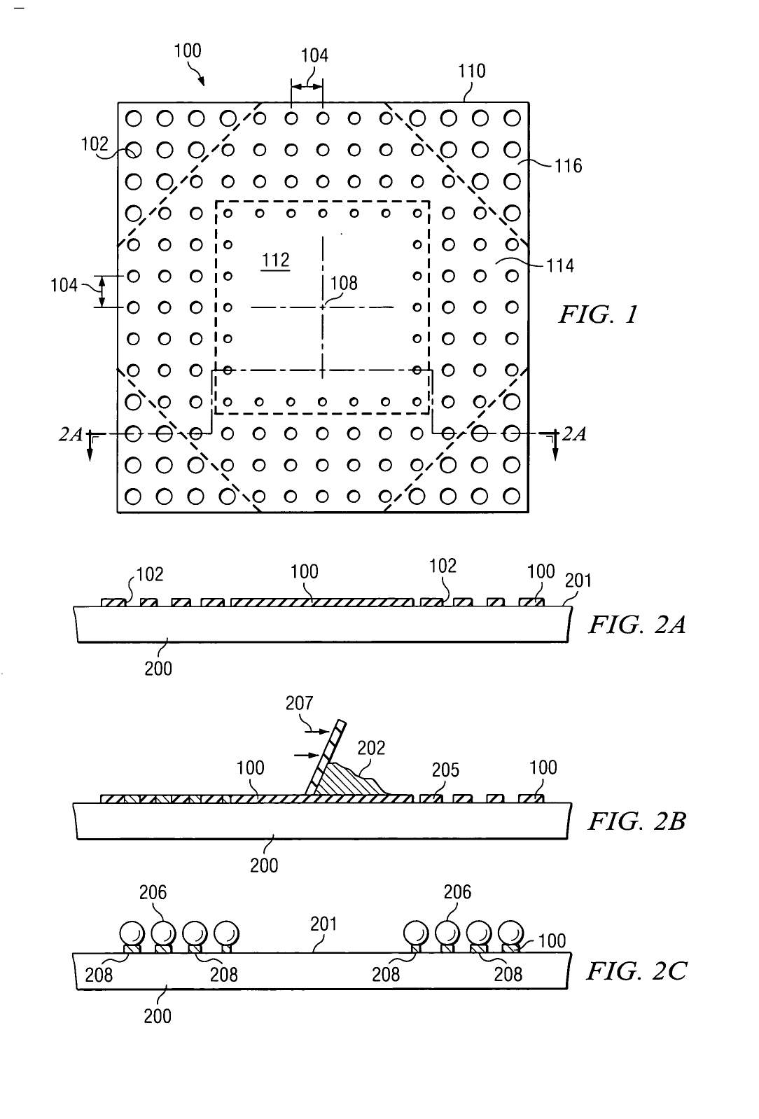

Example embodiments of the present invention and their advantages are best understood by referring now to FIG. 1 through 2C of the drawings, in which like numerals refer to like parts.

FIG. 1 is a plan view of a stencil 100 used in forming ball grid array packages according to an embodiment of the present invention. Stencil 100 functions to determine a particular pattern for solder paste regions 208 (FIG. 2C) during the ball attach process for BGA packages. Stencil 100 may be formed from any suitable material; however, stencil 100 is typically formed from stainless steel or other suitable metal. In addition, stencil 100 is relatively thin, typically having a thickness between approximately 5-10 mils, although other suitable thicknesses may be utilized.

In the illustrated embodiment, stencil 100 includes a plurality of generally circular holes 102 formed therein that function to define the configuration of solder paste regions 208. Shapes other than circles may be utilized for generally circular holes 102; however, because of the nature of solder balls used in BGA packages, the shape is generally circular. Generally circular holes 102 may be formed in stencil 100 with any suitable pattern; however, a typical pattern for generally circular holes 102 is an array in which generally circular holes 102 are aligned in rows and columns with a pitch 104. However, the pattern and spacing of generally circular holes 102 depends on the type BGA package being fabricated. For example, the type of BGA package that is formed using stencil 100 is a Texas Instruments, Inc. MicroStar BGA™, model no. GGU (S-PBGA-N144). As such, there are 13 rows and 13 columns of generally circular holes 102 formed in stencil 100. Pitch 104 for this particular BGA package is approximately 0.8 mils. For other BGA packages, pitch 104 is typically between approximately 0.5 millimeter and 1.0 millimeter. However, depending on the type of BGA package being formed, generally circular holes 102 may have any suitable pitch 104 and any suitable arrangement.

One of the most important components of BGA packages is solder ball coplanarity. Coplanarity is generally defined as the unilateral tolerance zone measured upward from the seating plane of the solder balls. Poor coplanarity leads to poor quality and poor reliability, which reduces productivity and yield for BGA packages. In addition, it may require a rework at the ball inspection process and reduce cycle time. Poor coplanarity is often caused by BGA package warpage due to the coefficient of thermal expansion mismatch involved during the molding process. Two-sided integrated circuits such as dual in-line packages typically do not have this warpage problem. Therefore, in accordance with the teachings of the present invention, stencil 100 is designed to account for package warpage by increasing the volume of solder paste for solder paste regions 208 at locations where the most warpage is expected. This is facilitated by generally increasing the diameters of generally circular holes 102 as the location of generally circular holes 102 extends farther from a center 108 of stencil 100.

As one example, referring to FIG. 1, stencil 100 is generally square-shaped and has an array of generally circular holes 102 as shown. Stencil 100 is broken down into three regions: a generally square-shaped center region 112, a generally square-shaped first outer region 114 that is oriented approximately 45 degrees from center region 112, and a second outer region 116 defined by triangles disposed at the four corners of stencil 100. The generally circular holes 102 in center region 112 have smaller diameters than the generally circular holes 102 in first outer region 114, which in turn have smaller diameters than the generally circular holes 102 associated with second outer region 116. For example, the diameter of each of the generally circular holes 102 of first outer region 114 is approximately ten to twenty percent greater than the diameter of each of the generally circular holes 102 of center region 112, and the diameter of each of the generally circular holes 102 of second outer region 116 is approximately five to ten percent greater than the diameter of each of the generally circular holes of first outer region 114. Other suitable percentages may be utilized depending on the type of BGA package being fabricated.

In an embodiment where stencil 100 is used to fabricate a MicroStar BGA™ package (Model No. GGU (S-PBGA-N144)) as described above, generally circular holes 102 associated with center region 112 have a diameter of approximately 0.28 millimeters, the generally circular holes 102 associated with first outer region 114 have a diameter of approximately 0.32 millimeters, and the generally circular holes 102 associated with second outer region 116 have a diameter of approximately 0.34 millimeters. This arrangement of generally circular holes 102 forming stencil 100 compensates for the majority of the warpage for this particular type of MicroStar BGA™ package, which happens to occur at the corners of this BGA package.

Although stencil 100 as illustrated in FIG. 1 is specific to one particular type of BGA package, stencils for other types of BGA packages follow the teachings of the present invention, which is to generally increase diameters of the holes formed in a stencil as the holes move further away from the center of the stencil. The particular diameters of the holes, the number of hole regions, and the percent increase in diameter moving from one region to another, depends on the type of BGA package being fabricated. This is determined in any suitable manner, such as through trial and error, experimentation, or using suitable engineering calculations that factor in the parameters of the particular BGA package fabrication process.

The term “generally increasing” as used herein does not mean that a particular generally circular hole 102 that is farther from center 108 than another particular generally circular hole 102 has a larger diameter. It merely means that, on average, the diameters of generally circular holes 102 increase as the location of generally circular holes 102 move further away from center 108 and towards a perimeter 110 of stencil 100. For example, a particular generally circular hole as referenced by numeral 103 may be slightly further away from center 108 than a particular generally circular hole as referenced by numeral 105, yet have a slightly smaller diameter.

FIGS. 2A-2C are a series of cross-sectional elevation views illustrating an example method of packaging a ball grid array according to one embodiment of the invention in which stencil 100 is utilized. Referring to FIG. 2A, stencil 100 is shown to be engaging a first surface 201 of a substrate 200. Substrate 200 may be any suitable substrate formed from any suitable material, such as polyimide, ceramic, FR4, and the like. Typically, substrate 200 has circuitry formed therein and one or more encapsulated integrated circuit dies coupled to a second side 203. As illustrated in FIG. 2A, generally circular holes 102 are shown to have a generally longitudinal cylindrical cross-section; however, other suitable longitudinal cross-sectional shapes may be utilized, such as trapezoidal. After stencil 100 is properly positioned on first surface 201 of substrate 200, then a solder paste 202 is utilized to fill in generally circular holes 102, as illustrated in FIG. 2B.

FIG. 2B illustrates a squeegee 204 directing solder paste 202 over a surface 205 of stencil 100 in order to fill generally circular holes 102. Generally, squeegee 204 starts at one end of sensor 100 and spreads solder paste 202 over surface 205 of stencil 100 in the direction as indicated by arrow 207. This process is generally known as screen printing in the industry and is well known to those skilled in the art. Other suitable methods of filling generally circular holes 102 with solder paste 202 is contemplated by the present invention. After solder paste 202 has filled generally circular holes 102, stencil 100 is then removed from first surface 201 of substrate 200, thereby leaving solder paste regions 208 exposed disposed outwardly from substrate 200, as illustrated in FIG. 2C.

FIG. 2C illustrates solder paste regions 208 disposed outwardly from first surface 201. Solder paste regions 208 function to couple a plurality of solder balls 206 to substrate 200 using any suitable ball attachment process. As indicated by FIG. 2C, because the generally circular holes 102 located further away from center 108 of sensor 100 have a larger diameter than those closer to center 108, there is more volume of solder paste in solder paste regions 208 where the most package warpage is expected to take place. After the mounting of solder balls 206 to solder paste regions 208, suitable inspection and reflow processes, which are well known in the industry, are carried out to permanently attach solder balls 206 to substrate 200. The BGA package being fabricated may then be completed.

Thus, any package warpage that may take place during the molding process due to coefficient of thermal expansion mismatch is already compensated for in the present invention by designing sensor 100 with generally circular holes 102 as described above. This leads to proper dimensions and tolerances for the completed BGA package, which greatly improves productivity and yield and eliminates any rework at the ball inspection process.

Although embodiments of the invention and their advantages are described in detail, a person skilled in the art could make various alterations, additions, and omissions without departing from the spirit and scope of the present invention, as defined by the appended claims.

1. A system for forming ball grid array packages, comprising:
a substrate;
a stencil engaging a first surface of the substrate, the stencil comprising:
a center region having a first set of generally circular holes formed therein; and
a first outer region disposed radially outwardly from the center region and having a second set of generally circular holes formed therein, wherein the diameter of each of the generally circular holes of the second set is greater than the diameter of each of the generally circular holes of the first set;
a solder paste disposed outwardly from the stencil; and
a squeegee operable to spread the solder paste over the stencil to fill the first and second set of generally circular holes, thereby creating a plurality of solder paste regions.

2. The system of claim 1, further comprising a plurality of solder balls configured to couple to respective ones of the solder paste regions.

3. The system of claim 1, wherein the diameter of each of the generally circular holes of the second set is approximately ten to twenty percent greater than the diameter of each of the generally circular holes of the first set.

4. The system of claim 1, wherein the stencil comprises a second outer region disposed radially outwardly from the first outer region and having a third set of generally circular holes formed therein, wherein the diameter of each of generally circular holes of the third set is greater than the diameter of each of the generally circular holes of the second set.

5. The system of claim 4, wherein the diameter of each of the generally circular holes of the third set is approximately five to ten percent greater than the diameter of each of the generally circular holes of the second set.

6. The system of claim 1, wherein the stencil has a generally square shape.

7. The system of claim 6, wherein center region is generally square shaped, and the first outer region is generally square shaped and oriented approximately 45 degrees with respect to the center region.

8. The system of claim 6, wherein the first and second set of generally circular holes are aligned in rows and columns, wherein a pitch between adjacent generally circular holes is between approximately 0.5 millimeter and 0.1 millimeter.

9. A method for forming ball grid array packages, comprising:
providing a substrate;
engaging a stencil with a first surface of the substrate, the stencil comprising:
a center region having a first set of generally circular holes formed therein; and
a first outer region disposed radially outwardly from the center region and having a second set of generally circular holes formed therein, wherein the diameter of each of the generally circular holes of the second set is greater than the diameter of each of the generally circular holes of the first set;
depositing solder paste over the stencil;
removing the stencil, thereby creating a plurality of solder paste regions on the substrate; and
coupling a plurality of solder balls to respective ones of the solder paste regions.

10. The method of claim 9, wherein the diameter of each of the generally circular holes of the second set is approximately ten to twenty percent greater than the diameter of each of the generally circular holes of the first set.

11. The method of claim 9, wherein the stencil comprises a second outer region disposed radially outwardly from the first outer region and having a third set of generally circular holes formed therein, wherein the diameter of each of generally circular holes of the third set is greater than the diameter of each of the generally circular holes of the second set.

12. The method of claim 11, wherein the diameter of each of the generally circular holes of the third set is approximately five to ten percent greater than the diameter of each of the generally circular holes of the second set.

13. The method of claim 9, further comprising providing the stencil with generally square shape.

14. The method of claim 13, further comprising:
providing the center region with a generally square shape;
providing the first outer region with a generally square shape; and
orienting the first outer region approximately 45 degrees with respect to the center region.

15. The method of claim 9, further comprising aligning the first and second set of generally circular holes in rows and columns, wherein a pitch between adjacent generally circular holes is between approximately 0.5 millimeter and 0.9 millimeter.

16. A system for forming ball grid array packages, comprising:
a substrate;
a stencil engaging a first surface of the substrate, the stencil comprising a plurality of generally circular holes formed therein, the diameters of the generally circular holes generally increasing as the location of the generally circular holes extends farther from a center of the stencil and toward a perimeter of the stencil;
a solder paste disposed outwardly from the stencil; and
a squeegee operable to spread the solder paste over the stencil to fill the generally circular holes, thereby creating a plurality of solder paste regions.

17. The system of claim 16, further comprising a plurality of solder balls configured to couple to respective ones of the solder paste regions.

18. The system of claim 16, wherein the stencil has a generally square shape.

19. The system of claim 18, wherein the generally circular holes are arranged in an array of rows and columns.

20. The system of claim 19, wherein a pitch between adjacent generally circular holes is between approximately 0.5 millimeter and 0.1 millimeter.
